(19) United States
(12) Patent Application Publication
(10) Pub. No.: US 2004/0192047 A1
(43) Pub. Date: Sep. 30, 2004

(54) Method of pre-etching glass substrate for reducing releasing time

(75) Inventors: Long-Sun Huang, Taipei (TW); Bing-Ru Chen, Pingtung County (TW); Shi-Yuan Tseng, Taipei City (TW)

Correspondence Address: HAVERSTOCK & OWENS LLP, 162 NORTH WOLFE ROAD, SUNNYVALE, CA, 94086, US

(73) Assignee: Walsin Lihwa Corp.

(21) Appl. No.: 10/794,286

(22) Filed: Mar. 3, 2004

(30) Foreign Application Priority Data
Mar. 6, 2003 (TW) 092104870

(51) Int. Cl. H01L 21/00; H01L 21/302; H01L 21/461

(52) U.S. Cl. 438/691

(57) ABSTRACT

A method of pre-etching a glass substrate for reducing a post-releasing time is provided. The method includes steps of: The glass substrate, a micro-structure and a silicon substrate are provided. The glass substrate is connected with the micro-structure. A first etching process is performed on the glass substrate for reducing the area of the glass substrate connected with the micro-structure. The micro-structure is connected with the silicon substrate and a second etching process is performed on the glass substrate for removing the micro-structure from the glass substrate.

### FIELD OF THE INVENTION

The present invention is related to a method for reducing a post-releasing time of glass substrate and more particularly to a method of pre-etching a glass substrate for reducing a post-releasing time thereof.

### BACKGROUND OF THE INVENTION

The Micro Electro Mechanical System which is an integrated micro-component or system includes electronic and mechanical parts made by the batch manufacture method of Integrated Circuit. The size of the elements or system is from micrometer to millimeter. MEMS is a new field that many countries in the world have developed zealously. The application of Micro Electro Mechanical System could be very broad, including manufacture industry, information industry, aerospace industry, traffic and transportation industry, civil engineering industry and medical industry.

In the common manufacturing process of Micro Electro Mechanical System or semiconductor the components needs to be connected with a glass substrate for moving the micro-structure easily. Because it is more convenient to move a bigger glass substrate than to move a micro-structure. Afterward, the components are usually connected or combined with another component. Since the glass substrate is not included in the original structural design. It needs to be taken off ultimately. The general way to take off the glass substrate is the wet-etching by Hydrofluoric Acid. However, Hydrofluoric Acid is a strong acid and has the feature of corroding many kinds of material including mono-crystalline silicon, poly-crystalline silicon, silicon nitride, and metal, and etc, which are common materials used in Micro Electro Mechanical System or semiconductor process. Besides, in the process of removing the glass substrate, other parts of the structure will be etched by Hydrofluoric Acid as well and the original structure will be destroyed. Therefore, the wet-etching time by Hydrofluoric Acid must be shorter in order to reduce the corrosive influence of Hydrofluoric Acid. The effect of wet-etching by Hydrofluoric Acid continues until the components are removed from the glass substrate so it is important to remove the glass substrate quickly.

In order to overcome the drawbacks and solve the problems encountered in the prior art, a method of pre-etching glass substrate for reducing releasing time is provided in the invention.

### SUMMARY OF THE INVENTION

It is therefore an object of the present invention to provide an isotropic pre-etching process performed on the glass substrate by Hydrofluoric Acid in advance for reducing the post-releasing time. Therefore, the structure would need shorter time to release the glass substrate so as to reduce the time that the structure was attacked by Hydrofluoric Acid and to decrease the damage of the structure.

According to one aspect of the present invention, a method of pre-etching a glass substrate for reducing a post-releasing time thereof is provided. The steps are as follows. The glass structure, a micro-structure and a silicon substrate are provided. The glass substrate is connected with the micro-structure. A first etching process on the glass substrate is performed for reducing an area of the glass substrate connected with the micro-structure. The micro-structure is connected with the silicon substrate. And a second etching process is performed on the glass substrate for removing the micro-structure from the glass substrate.

Preferably, the micro-structure includes a Micro Electro Mechanical system structure and an Integrated Circuit structure.

Preferably, the silicon substrate includes a Micro Electro Mechanical system structure and an Integrated Circuit structure.

Preferably, the first etching process is an isotropic wet-etching process by a Hydrofluoric Acid.

Preferably, the second etching process is a wet-etching process by a Hydrofluoric Acid.

According to another aspect of the present invention, a method for reducing a post-releasing time of a glass basement through a pre-etching process is provided. It includes the steps of: The glass basement, a micro-structure and a silicon substrate are provided. The glass basement is bonded with the micro-structure. A first wet-etching process is performed for reducing an area of the glass basement connected with the micro-structure. The micro-structure is connected with the silicon substrate. And a second wet-etching process is performed on the glass basement for removing the micro-structure from the glass basement.

Preferably, the micro-structure includes a Micro Electro Mechanical system structure and an Integrated Circuit structure.

Preferably, the silicon substrate includes a Micro Electro Mechanical system structure and an Integrated Circuit structure.

Preferably, the first wet-etching process is an isotropic wet-etching process by a Hydrofluoric Acid.

Preferably, the second wet-etching process is performed by a Hydrofluoric Acid.

According to another aspect of the present invention, a method of pre-etching a glass basic material for reducing a post-releasing time is provided. It includes steps of: The glass basic material, a micro-structure and a silicon substrate are provided. The glass basic material is bonded with the micro-structure. A first wet-etching process is performed on the glass basic materical for reducing an area of the glass basic material connected with the micro-structure, wherein the first wet-etching process is an isotropic wet-etching process. The micro-structure is connected with the silicon substrate. And a second wet-etching process is performed on the glass basic material for removing the micro-structure from the glass basic material.

Preferably, the micro-structure includes a Micro Electro Mechanical system structure and an Integrated Circuit structure.

Preferably, the silicon substrate includes a Micro Electro Mechanical system structure and an Integrated Circuit structure.

Preferably, the isotropic wet-etching process is performed by a Hydrofluoric Acid.

Preferably, the second wet-etching process is performed by a Hydrofluoric Acid.

The foregoing and other features and advantages of the present invention will be more clearly understood through the following descriptions with reference to the drawings, wherein:

### BRIEF DESCRIPTION OF THE DRAWINGS

FIGS. 1(a), (b), (c) and (d) are schematic views showing steps of a method of pre-etching glass substrate for reducing the post-releasing time according to an embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

The present invention is a new way for reducing the releasing time of the glass substrate of general Micro Electro Mechanical System structure or semiconductor structure. Through the method provided in the present invention, the time that the Hydrofluoric Acid attacks the structure is reduced and the shape and size of the structure are avoided from being changed so as to avoid the functional errors caused by the components with inaccurate structures

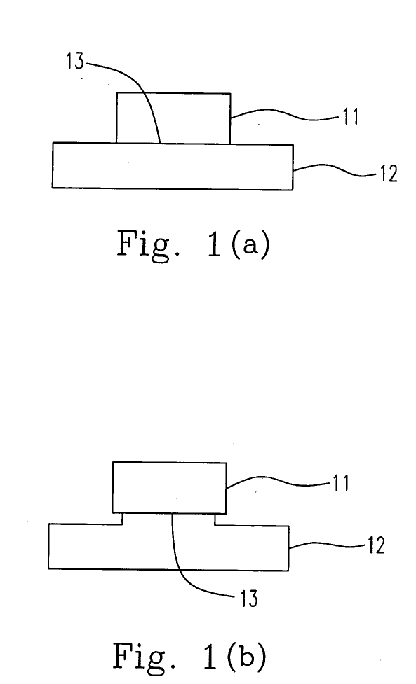

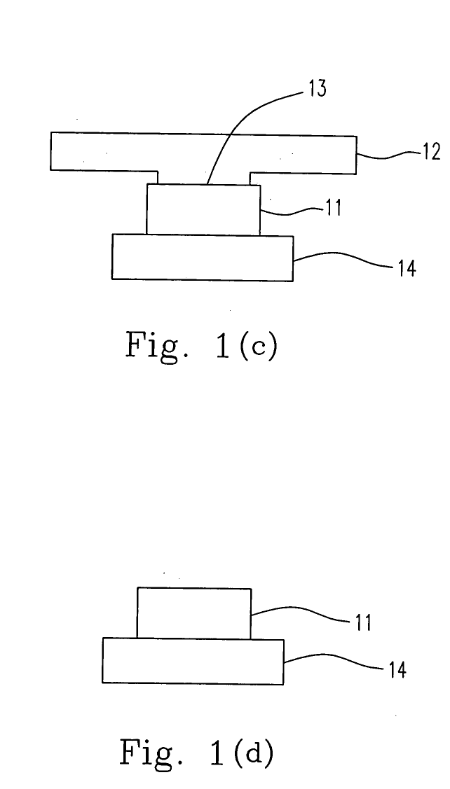

Please refer to FIGS 1(a), (b), (c) and (d), which are schematic views showing the steps of pre-etching glass substrate for reducing the post-releasing time according to one embodiment of the present invention. The steps are as follows.

First, the glass substrate 12, the micro-structure 11 and the silicon substrate 14 are provided. Next, the glass substrate 12 is connected with the micro-structure 11, as shown in FIG. 1(a). Afterwards, an isotropic wet-etching process is performed on the glass substrate 12 by Hydrofluoric Acid in advance. The process could reduce the area of the glass substrate 12 connected with the micro-structure 11 as shown in FIG. 1(b). Referring to FIG. 1(b), the area of the glass substrate 12 connected with the micro-structure 11 has become much smaller, that is the result of performing an isotropic wet-etching process on the glass substrate 12 by Hydrofluoric Acid. Then, the micro-structure 11 is connected with the silicon substrate 14 as shown in FIG. 1(c). Finally, the glass structure 12, the micro-structure 11 and the silicon substrate 14 are put into the Hydrofluoric Acid for performing another wet-etching process. The glass substrate 12 is removed from the micro-structure 11, as shown in FIG. 1(d).

Because the glass substrate 12 is a temporary structure originally, it becomes useless after the micro-structure 11 is connected with the silicon substrate 14 and needs to be released. The isotropic wet-etching process by Hydrofluoric Acid to remove the glass substrate 12 is necessary. Only that a small amount of Hydrofluoric Acid would be enough to remove the glass substrate 12 from the micro-structure 11.

The present invention provides an isotropic pre-etching process performed on glass substrate through the Hydrofluoric Acid for reducing the post-releasing time of the structure. The time that Hydrofluoric Acid attacks the structure is reduced and the damages of the structure are decreased. The method improves the prior art efficiently and it has industrial utility so as to achieve the goal of the present invention.

While the invention has been described in terms of what are presently considered to be the most practical and preferred embodiments, it is to be understood that the invention need not to be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method of pre-etching a glass substrate for reducing a post-releasing time thereof, comprising steps of:
providing said glass substrate, a micro-structure and a silicon substrate;
connecting said glass substrate with said micro-structure;
performing a first etching process on said glass substrate for reducing an area of said glass substrate connected with said micro-structure;
connecting said micro-structure with said silicon substrate; and
performing a second etching process on said glass substrate for removing said micro-structure from said glass substrate.

2. The method according to claim 1 wherein said micro-structure comprises a Micro Electro Mechanical system structure and an Integrated Circuit structure.

3. The method according to claim 1 wherein said silicon substrate comprises a Micro Electro Mechanical system structure and an Integrated Circuit structure.

4. The method according to claim 1 wherein said first etching process is an isotropic wet-etching process by a Hydrofluoric Acid.

5. The method according to claim 1 wherein said second etching process is a wet-etching process by a Hydrofluoric Acid.

6. A method for reducing a post-releasing time of a glass basement through a pre-etching process, comprising steps of:
providing said glass basement, a micro-structure and a silicon substrate;
bonding said glass basement with said micro-structure;
performing a first wet-etching process on said glass basement for reducing an area of said glass basement connected with said micro-structure;
connecting said micro-structure with said silicon substrate; and
performing a second wet-etching process on said glass basement for removing said micro-structure from said glass basement.

7. The method of according to claim 6 wherein said micro-structure comprises a Micro Electro Mechanical system structure and an Integrated Circuit structure.

8. The method according to claim 6 wherein said silicon substrate comprises a Micro Electro Mechanical system structure and an Integrated Circuit structure.

9. The method according to claim 6 wherein said first wet-etching process is an isotropic wet-etching process by a Hydrofluoric Acid.

10. The method according to claim 6 wherein said second wet-etching process is performed by a Hydrofluoric Acid.

11. A method of pre-etching a glass basic material for reducing a post-releasing time thereof, comprising steps of:
providing said glass basic material, a micro-structure and a silicon substrate;
bonding said glass basic material with said micro-structure;
performing a first wet-etching process on said glass basic material for reducing an area of said glass basic material connected with said micro-structure wherein said first wet-etching process is an isotropic wet-etching process;
connecting said micro-structure with said silicon substrate; and
performing a second wet-etching process on said glass substrate for removing said micro-structure from said glass basic material.

12. The method according to claim 11 wherein said micro-structure comprises a Micro Electro Mechanical system structure and an Integrated Circuit structure.

13. The method according to claim 11 wherein said silicon substrate comprises a Micro Electro Mechanical system structure and an Integrated Circuit structure.

14. The method according to claim 11 wherein said isotropic wet-etching process is performed by a Hydrofluoric Acid.

15. The method according to claim 11 wherein said second wet-etching process is performed by a Hydrofluoric Acid.
